(19) United States
(12) Patent Application Publication
(10) Pub. No.: US 2004/0024941 A1
(43) Pub. Date: Feb. 5, 2004

(54) Method and apparatus for supporting hot-plug cache memory

(75) Inventors: Sompong Paul Olarig, Pleasanton, CA (US); John E. Jenne, Houston, TX (US)

Correspondence Address: HEWLETT-PACKARD COMPANY, INTELLECTUAL PROPERTY ADMINISTRATION, P.O. BOX 272400, fort collins, CO, 80527-2400, US

(73) Assignee: Compaq Information Technologies Group, L.P., Houston, TX (US)

(21) Appl. No.: 10/210,230

(22) Filed: Jul. 31, 2002

(51) Int. Cl. H05K 7/10; G06F 13/00

(52) U.S. Cl. 710/302

(57) ABSTRACT

A cache memory controller allows hot-plug insertion and removal of cache memory modules. After detecting an insertion, the controller waits a predetermined time, then determines the size and speed of the added cache memory modules. If the inserted cache memory module is acceptable, then tag memory is reconfigured to correspond to the inserted memory. The added cache memory is initialized. After successful insertion and initialization, a status bit in the cache controller is set to indicate memory has been added. Prior to removal of a cache memory module, the cache is flushed to main memory and further cache transactions are disabled. After removal of the cache memory module, tag memory is reconfigured to mark a corresponding portion of the tag memory as unused. After successful removal of the cache memory module and reconfiguration of the tag memory, the cache memory controller enables new cache memory transactions.

### CROSS-REFERENCE TO RELATED APPLICATIONS

Not Applicable.

### STATEMENTS REGARDING FEDERALLY SPONSORED RESEARCH OR DEVELOPMENT

Not Applicable.

### REFERENCE TO A MICROFICHE APPENDIX

Not Applicable.

### BACKGROUND OF THE INVENTION

1. Field of the Invention

The invention generally relates to cache memory of a computer system, and in particular to a technique for hot-plug insertion and removal of cache memory modules.

2. Description of the Related Art

Cache memory has been widely used in the computer industry to increase the performance of computer systems. Cache memory is a special high speed memory designed to supply a processor with the most frequently requested data including instructions. Data located in cache memory can typically be accessed many times faster than data located in main memory.

In general, there are two levels of cache memory: internal cache, which is typically located inside a processor chip, and external cache, typically located on a system board and coupled to the processor via a host bus. A cache controller typically interfaces between the processor, cache memory, and main memory, which may have a separate main memory controller.

The cache controller typically receives memory transactions from the processor, and supplies data (including instructions) from the cache memory if a memory request from the processor is found in the cache, referred to as a “cache hit.” If the memory request is not satisfiable from the cache, referred to as a “cache miss,” the cache controller will copy data obtained from main memory into the cache, to increase the probability of a cache hit on the next transaction.

Because cache memory is generally more expensive than main memory, system designers attempt to configure a cache memory with an appropriate amount of memory, typically balancing performance benefits with system cost. In some implementations, system designers have packaged cache memory as internal cache memory on the same chip as the cache controller, which can provide performance benefits at the cost of flexibility. In other implementations, system designers have used external cache memory modules. Such external cache memory is typically a static RAM (SRAM) module instead of the dynamic RAM (DRAM) used for main memory. In systems with internal cache memory, the cache memory size is typically fixed at chip manufacture, with no provision for addition of additional cache memory or for removing or replacing failed cache memory. Systems with external cache memory typically allow for insertion, removal, or replacement of external cache memory modules during a non-operational state of the system.

A failure in a cache memory module can require removal of the failed cache memory module during a non-operational state, which state may have been caused by the cache memory module failure. Currently, relatively large external cache memories are being used in servers and high end non-server systems. In addition, networking products, such as routers and switches, are implementing caches. As cache memories grow larger, the probability and impact of a cache memory failure typically increase. Further, as systems become more heavily used, cache memory size increases may become more desirable.

Modem server systems and networking products are designed for continuous operation, and shutdowns of such servers are significant events, which are to be avoided if possible.

### BRIEF SUMMARY OF THE INVENTION

Briefly, a disclosed technique provides hot plug replacement of cache memory.

One embodiment allows hot plug insertion of cache memory by signaling a cache memory controller to start an insertion operation; hot-plug inserting a cache memory module into an open cache memory slot; validating the cache memory module characteristics; and if the step of validating the cache memory module characteristics successfully validates the cache memory module characteristics, indicating successful insertion of the cache memory module.

In a further embodiment, the technique further includes flushing a cache tag memory and reconfiguring the cache tag memory which can include marking an unused portion of the tag memory as being in use, the unused portion corresponding to a size of the cache memory module.

In another embodiment, validating the cache memory module characteristics includes waiting a predetermined time after completion of the step of inserting the cache memory module then determining a size of the cache memory module; determining an access time acceptability of the cache memory module; and if the cache memory module access time is not acceptable, indicating failure, otherwise indicating successful validation. In a further embodiment, the cache memory module can report module characteristics, and determining a size of the cache memory module includes issuing a request to the cache memory module for the size of the cache memory module and receiving the size of the cache memory module responsive to the step of issuing a request. In yet a further embodiment, the cache memory module supports an auto-detection technique, such as Serial Presence Detect (SPD). Issuing a request includes issuing an auto-detection read request and receiving the size includes receiving an auto-detection characteristics block responsive to the auto-detection read request and extracting the size from the auto-detection characteristics block.

In another further embodiment, the cache memory can report module characteristics, and determining the access time of the cache memory module includes issuing a request to the cache memory module for the access time of the cache memory module; receiving the access time from the cache memory module responsive to the step of issuing; if the access time is at least as great as a predetermined access time value, indicating the access time is acceptable; and otherwise, indicating the access time is unacceptable.

In yet a further embodiment, the cache memory module supports an auto-detection technique, such as Serial Presence Detect (SPD). Issuing a request is performed by issuing an auto-detection read request; receiving the access time is performed by receiving an auto-detection characteristics block responsive to the auto-detection read request and extracting the access time from the auto-detection characteristics block.

In another further embodiment, determining a size includes (a) writing a predetermined value to an address location of the cache memory module; (b) reading the address location, receiving a read value; (c) comparing the read value to the predetermined value; (d) if the read value equals the predetermined value, incrementing the address location and repeating steps (a)-(d); and (e) otherwise, computing the cache memory module size from the current value of the address location.

In another further embodiment, determining an access time is performed by writing a predetermined value to a location of the cache memory module; reading the location, receiving a read value; comparing the read value to the predetermined value; and if the read value equals the predetermined value, indicating the access time is acceptable; otherwise, indicating the access time is unacceptable.

In another embodiment, the technique further includes setting a status bit to indicate successful insertion of the cache memory.

In yet another embodiment, the technique further includes initializing the cache memory module by writing a predetermined value to every memory location of the cache memory module.

In another embodiment, a disclosed technique of hot-plug removal of cache memory includes signaling a cache memory controller to start a removal operation; flushing the cache memory to a main memory; disabling further cache transactions; hot-plug removing the cache memory module; reconfiguring a tag memory for the cache controller; and enabling further cache transactions.

In a further embodiment, reconfiguring a tag memory includes marking a portion of the tag memory corresponding to the cache memory module as unused.

In another further embodiment, disabling further cache transactions is performed by asserting a hold-off signal to a processor coupled to the cache memory controller; while enabling further cache transactions is performed by deasserting the hold-off signal.

A disclosed technique of one embodiment provides for hot-plug replacing cache memory by hot-plug removing a cache memory module; hot-plug inserting a replacement cache memory module; and reconfiguring a tag memory for a cache memory controller to correspond to the replacement cache memory module.

In another embodiment, a cache memory subsystem adapted for hot-plug insertion and removal of cache memory includes: a plurality of slots for insertion of cache memory modules; a tag memory; and a cache controller, coupled to the tag memory and the plurality of slots, which includes circuitry to detect insertion of a cache memory module in one of the plurality of slots; circuitry to validate a cache memory module detected by the circuitry for detecting; and circuitry to indicate successful insertion of the cache memory module.

In a further embodiment, the cache controller further includes circuitry to flush the tag memory responsive to insertion of a cache memory module into one of the plurality of slots; circuitry to allocate an unused portion of the tag memory to the cache memory module.

In another further embodiment, the circuitry for validating the cache memory module includes a timer adapted to start a predetermined delay period upon insertion of the cache memory module; circuitry to determine characteristics of the cache memory module upon expiration of the predetermined delay period; and circuitry to indicate successful validation if the characteristics of the cache memory module are acceptable, otherwise to indicate failure.

In a yet further embodiment, the circuitry to determine characteristics of the cache memory module includes circuitry to determine a memory capacity of the cache memory module. If the cache memory module supports an auto-detection technique, such as Serial Presence Detect (SPD), the circuitry to determine a memory capacity can include circuitry to send an auto-detection read signal to the cache memory module; circuitry to read an auto-detection block from the cache memory module; and circuitry to extract a memory capacity from the auto-detection block. If the cache memory module does not support auto-detection, the circuitry to determine a memory capacity can include circuitry to repeatedly write a predetermined value then read the cache memory until reading fails to return the predetermined value.

In another further embodiment, the circuitry to determine characteristics of the cache memory module includes circuitry to determine a memory access time of the cache memory module. If the cache memory module supports an auto-detection technique, such as Serial Presence Detect (SPD), the circuitry to determine a memory access time can include circuitry to send an auto-detection read signal to the cache memory module; circuitry to read an auto-detection block from the cache memory module; and circuitry to extract a memory access time from the auto-detection block. If the cache memory module does not support auto-detection, the circuitry to determine a memory access time can include circuitry to write then read the cache memory with a predetermined value; circuitry to indicate a memory access time of a predetermined access time if the circuitry to write then read successfully reads data written to the cache memory module; otherwise, to indicate an access time greater than the predetermined access time for the cache memory module.

In another further embodiment, the circuitry to indicate successful validation includes circuitry to indicate successful validation if the memory access time is not greater than a predetermined access time, otherwise to indicate failure.

In another embodiment, the cache controller further includes circuitry to flush cache memory to a main memory upon beginning a cache memory module removal operation; circuitry to indicate removal of a cache memory module can be performed; and circuitry to mark a portion of the tag memory corresponding to the cache memory module as unused. In a yet further embodiment, the cache controller further includes circuitry to prevent further cache memory transactions upon beginning a cache memory removal operation; and circuitry to allow further cache memory transactions upon completion of a cache memory module removal operation. The circuitry to prevent further cache memory transactions can include circuitry to assert a hold-off signal to a processor coupled to the cache memory controller. Similarly, the circuitry to allow further cache memory transactions can include circuitry to deassert a hold-off signal to a processor coupled to the cache memory controller.

A system according to the invention may implement various features of the various embodiments.

### BRIEF DESCRIPTION OF THE SEVERAL VIEWS OF THE DRAWINGS

A better understanding of the present invention can be obtained when the following detailed description of the preferred embodiment is considered in conjunction with the following drawings, in which:

FIG. 1 is a block diagram illustrating a portion of a computer system according to the one embodiment;

FIG. 2 is a block diagram illustrating a cache memory as in FIG. 1 with multiple cache memory modules;

FIG. 3 is a block diagram illustrating additional details of the cache controller of FIGS. 1-2;

FIGS. 4a-4d are flow charts illustrating a technique for inserting a cache memory module into one of the slots of FIG. 2 according to one embodiment; and

FIG. 5 is a flow chart illustrating a technique for removing a cache memory module according to a disclosed embodiment.

### DETAILED DESCRIPTION OF THE INVENTION

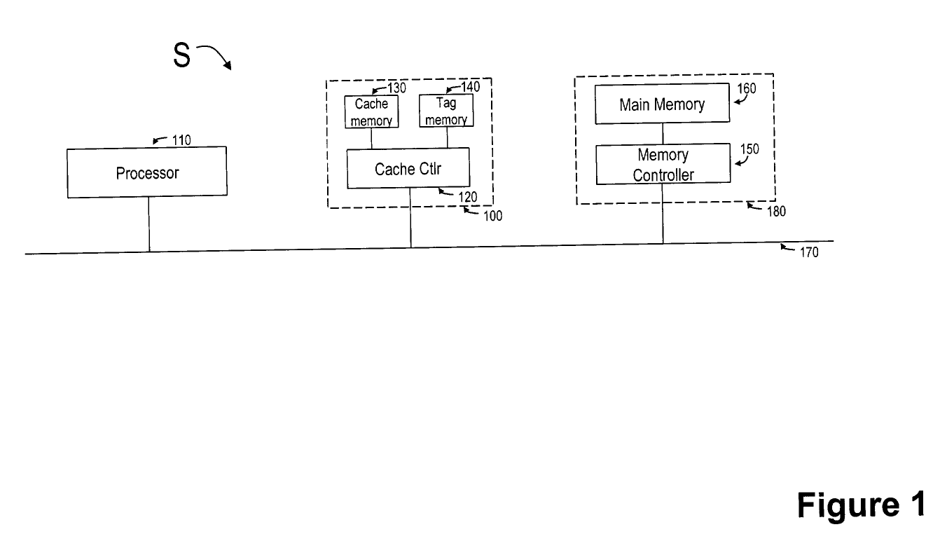

Turning now to FIG. 1, a block diagram illustrates portions of a computer system S according to one embodiment. Other conventional elements of the computer system S are omitted for clarity of the drawing. As shown in FIG. 1, a processor 110 is coupled to a host bus 170 and via the host bus 170 to a cache subsystem 100 and a main memory subsystem 180. The cache memory subsystem 100 includes a cache controller 120, a cache memory 130 and a tag memory 140. The main memory subsystem 180 includes a main memory controller 150 and a main memory 160, which can be implemented as a collection of memory modules. In the disclosed embodiment, the processor 110 and the main memory subsystem 180 are conventional elements and are not otherwise discussed. One skilled in the art will recognize that multiple processors 110 can be coupled to the host bus 170 and that other arrangements can be used and elements can also be connected to the host bus 170.

In one embodiment, the tag memory 140 is implemented as external tag memory 140 on separate tag memory modules. In another embodiment, the cache controller 120 and the tag memory 140 are implemented on a single chip, which can be the same chip as that containing the processor 110. In yet another embodiment, the cache controller 120 and the tag memory 140 are separate from each other and the processor 110. For clarity of the drawings and explanation, the cache controller 120 and the tag memory 140 will be discussed as if they were separate from each other and the processor 110.

The tag memory 140, as will be understood by one skilled in the art, is preferably a conventional tag memory. The tag memory 140 stores the tag address of the location of accessed data in the cache memory 130. An address supplied by the processor 110 or elsewhere for accessing the cache includes tag bits and cache index bits. Each cache line (the smallest amount of cache memory that can be accessed) has a tag, stored in the tag memory 140, which can be checked to determine if there is a cache bit. A tag memory 140 with only a single set of tags is referred to as “1-way” or direct mapped. A tag memory with multiple sets of tags would be referred to as an “n-way” set-associative cache. Various relationships of tag to cache can be employed.

The tag memory 140 determines how much of the main memory 160 can be cached in the cache memory 130. The following example illustrates how the tag memory 140 and the cache memory 130 interrelate.

In an exemplary system, the main memory contains 64 MB of memory, the cache memory 130 contains 512 KB, the tag memory 140 uses an 8-bit wide tag, and the cache line size is 32 bytes. These values are exemplary and illustrative only, and one skilled in the art will recognize that other memory sizes, other cache memory sizes and tag memory sizes and widths, and other cache line sizes can be used. A main memory of 64MB requires 26 address bits, thus typically uses 26 address lines. (2²⁶⁼⁶⁴MB.) The cache memory of 512KB requires 19 address bits, assuming byte-level addressing. (2¹⁹⁼⁵¹²KB.) Because the cache memory 130 in this example is accessed on a 32-byte cache line, which requires 5 address bits to specify the bytes within the cache line (2⁵⁼³²), the cache memory in this example uses 14 (19-5) address bits. Thus address lines A0-a4 specify the byte within a cache line and address lines A5-A18 specify the cache line, leaving address lines for seven bit tag, to allow the tag memory 140 to specify which address is currently using the cache line. The eighth bit in the exemplary tag memory 140 is used as a “dirty” bit, to indicate data in the cache line must be written back to main memory before reusing the cache line. Although this exemplary tag memory 140 uses a single “dirty” bit, other disclosed embodiments can use multiple bits to implement other cache protocols, such as “Modified, Exclusive, Shared, Invalid” (MESI) or “Modified, Owner, Exclusive, Shared, Invalid” (MOESI). Adding more main memory above 64 MB would not provide caching for the additional memory without additional tag memory to allow using wider (greater than seven-bit) tag entries, because multiple addresses would map to the same cache location, preventing determination of which cache line was cached. When checking the cache subsystem 100 for a cache hit, the cache controller 120 examines the address on the address lines, ignoring the low order bits (in this example, the low order five bits) that indicate the byte within a cache line. The tag memory 140 is then read at the address indicated by the address lines A5-A18. If the seven bits in the tag memory location indicated by address lines A5-A18 equal the address bits A19-A25, then a cache hit occurs; otherwise, a cache miss occurs.

The above example illustrates a direct-mapped cache. In an n-way set associative cache, the address lines A5-A18 of the above example identify n possible tag memory 140 locations that must be checked to determine whether a cache hit or cache miss occurs. Logic in the cache controller 120 would determine which n locations correspond to the memory address and search all n entries to determine a cache hit or cache miss.

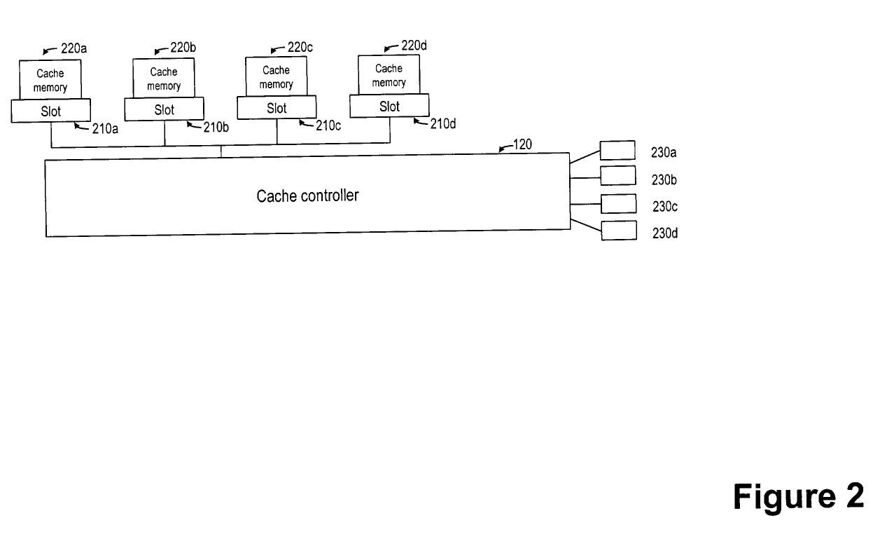

Turning to FIG. 2, a block diagram illustrates a more detailed view of the cache memory 130. The cache controller 120 is connected to a collection of slots 210a-210d, collectively referred to as the slots 210. These slots are used for plugging in cache memory modules 220a-220d, collectively referred to as the cache memory modules 220. The slots 210 can be conventional slots for plugging in external cache memory modules, and cache memory modules 220 can be conventional cache memory modules. Any convenient technique for removably attaching cache memory modules can be used.

In order for an operator to remove or insert a cache memory module 220, one or more of switches 230a-230d, collectively referred to as the switches 230, or other similar technique is used by an operator to signal the cache memory controller 120 that a removal or insertion is about to occur is provided. Such a signaling technique is used for other hot-plug device insertion and removal and is known in the art. The cache memory controller 120 responds to the signal from one or more of the switches 230 depending on whether a removal or insertion is indicated by the switch. Other techniques can be used. In one embodiment, switches connected to the cache memory modules 220a-220d can detect an attempt to remove a cache memory module and signal the cache memory controller 120.

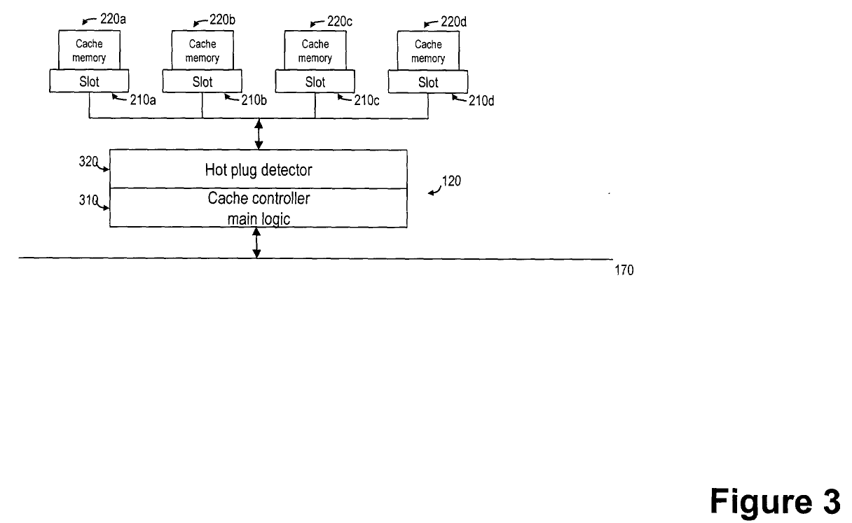

Turning to FIG. 3, a more detailed view of the cache controller 120 is shown. A cache controller main logic 310 contains conventional cache controller circuitry, which can be implemented in a separate chip from the hot-plug detector logic 320. The hot-plug detector logic 320 contains circuitry for detecting the use of switches 230, circuitry for detecting the insertion or removal of one of the cache memory modules 210, and circuitry for validating an inserted memory module by checking the memory capacity and access time. Additional circuitry of the hot-plug detector logic 320 interfaces with the cache memory controller main logic 310, including circuitry for causing the cache controller main logic to flush the tag memory 140, writeback any dirty lines, and flush the cache memory 130, and to reconfigure the tag memory 140 after insertion or removal of a cache memory module 210. Further circuitry in the hot-plug detector logic initializes a newly inserted cache memory module 210.

An embodiment of the cache controller 120 as shown in FIG. 3 allows the use of a hot-plug detector logic 310 from one supplier with a cache controller main logic 320 from another supplier. However, the arrangement and internal structure of the cache controller 120 as described above and in FIG. 3 is exemplary and illustrative only, and other arrangements and configurations can be used.

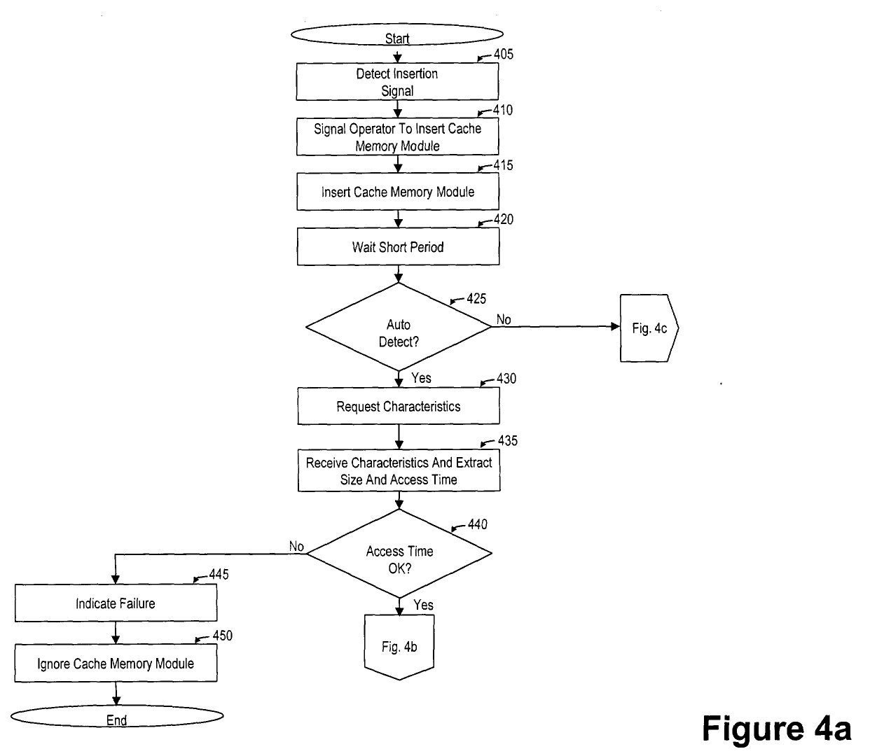

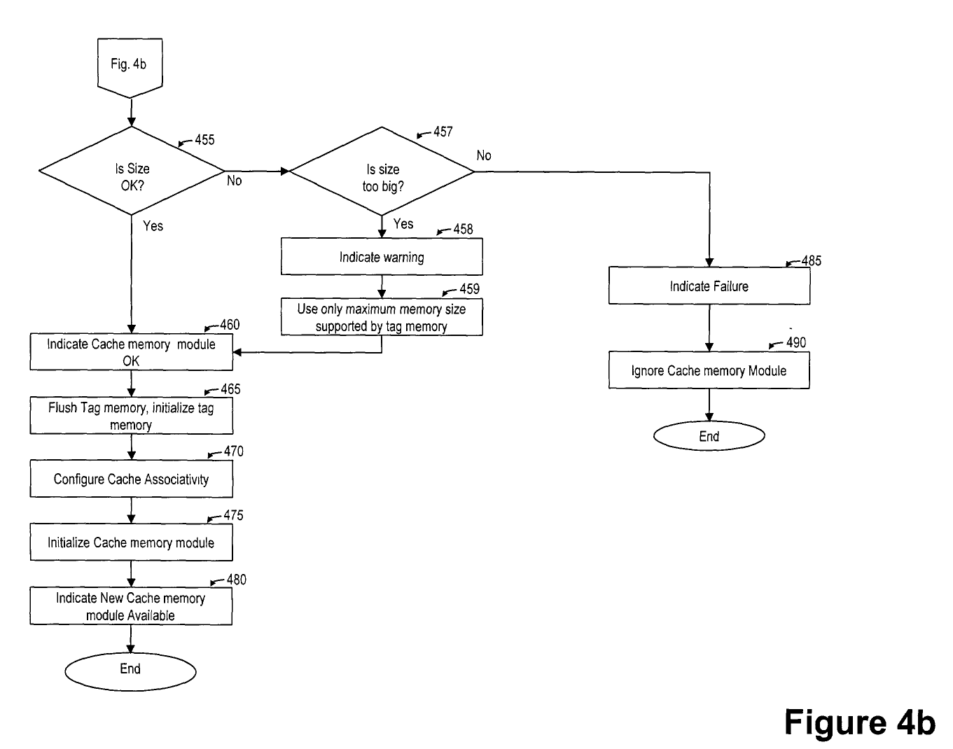

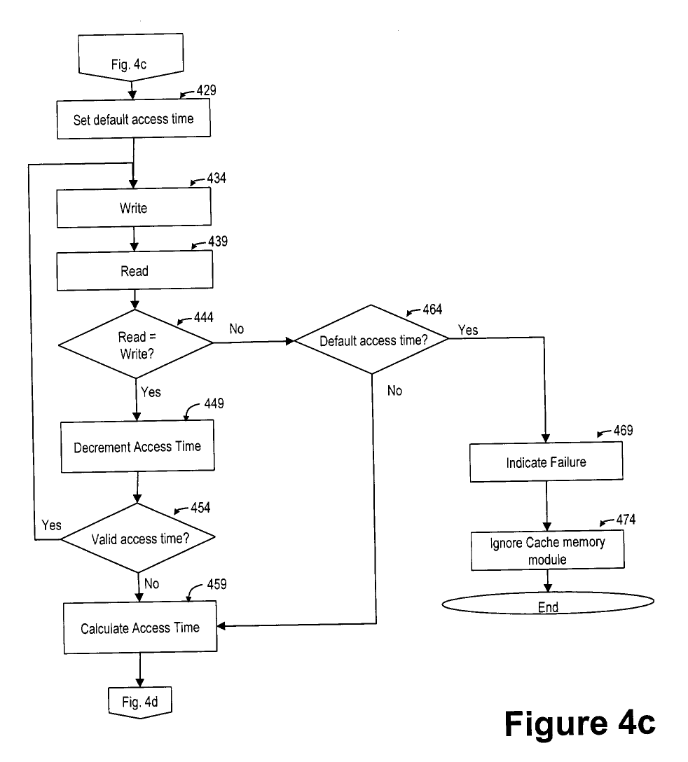

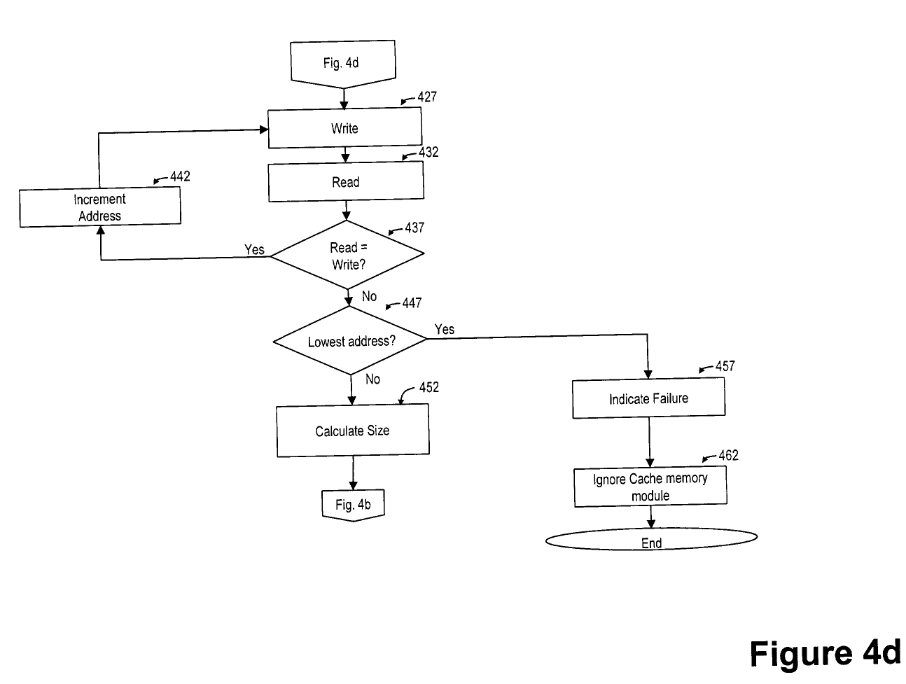

FIG. 4 is a flow chart illustrating inserting a cache memory module into an empty slot 210. In step 405, the cache controller 120 detects a signal from one of the switches 230 that a hot-plug insertion is to be performed. The cache controller 120 then signals the operation in step 410 to proceed with the insertion. Typical techniques for such a signal include lights or other operator-visible mechanisms that change color, light, or otherwise signal the action is safe to be performed. For example, in one embodiment, a multicolor light will be red initially turn amber upon use of one of the switches 230 and turn green when step 410 signals the operation to proceed. Other conventional signaling techniques can be used, such as messages on an operator console.

Once the operator recognizes the “go ahead” signal of step 410, the operator proceeds to insert the cache memory module 220 in step 415.

Conventional hot plug insertion techniques for main memory module and other devices use quick switches, typically Field Effect Transistor (FET) switches, to electrically isolate the newly inserted module or device during the insertion process, then electrically connect the newly inserted device, avoiding electrical spikes or other electrical noise causing problems or incorrectly generating signals to the device to which newly inserted module or device is connected. In one embodiment, such a conventional technique can be used. In another embodiment, a timer circuit 320 of the controller 120, shown in FIG. 3, causes the controller 120 to wait a predetermined short period in step 420 before proceeding to memory discovery in step 425. This delay value, which can be programmable and is preferably between one millisecond and one second, effectively debounces the noise that can be caused by the insertion of the cache memory module.

Further, to reduce operator error, operator indicators can be provided to indicate whether the cache memory module can be safely inserted or removed. One indicator technique uses multicolor light emitting diodes (LEDs), typically using red to indicate the cache memory module should not be inserted or removed, amber or yellow to indicate a request to insert or remove has been received, but the cache controller 120 is not ready for the insertion or removal, and green to indicate the cache memory module can safely be inserted or removed. Other indicator techniques, including multiple lights, differently colored or flashing lights, or non-light indicators can also be used.

Once the timer set in step 420 expires, the cache controller 120 needs to validate the inserted cache memory module 220, by checking the memory capacity (“size”) of the cache memory module 220 and the access time (“speed”) of the cache memory module 220. A memory module may have a speed too slow for the cache controller 120 to use, in which case the inserted cache memory module 220 should be ignored by the controller 120. A cache memory module 220 may have a size too big for the tag memory 140, in which case not all of the cache memory size of the inserted cache memory module 220 can be used.

In step 425, the cache controller 120 determines whether the inserted cache memory module 220 supports an auto-detect technique for reporting its characteristics. Although not conventionally used for the SRAM modules typically used for the cache memory modules 220, one such technique commonly used for DRAM modules is Serial Presence Detect, as defined in the PC SDRAM Serial Presence Detect (SPD) Specification, Revision 1.2B, published by Intel Corporation, a copy of which is incorporated herein by reference for all purposes. Modules using SPD can respond to an SPD signal from a controller or other device with an SPD characteristics data block, which includes both size and speed data. Although the following will be expressed in terms of SPD auto-detection, other kinds of auto-detect techniques that provide size and speed data can be used.

If step 425 determines the cache memory module 220 supports an auto detect technique, then in steps 430 and 435 the cache controller 120 requests the characteristics data then extracts the size and speed data returned from the cache memory module 220. If the SPD technique is used, in step 430 an SPD read will be initiated on the SDA and SA [2:0] signal lines to an EEPROM on the cache memory module 220. In step 435, the EEPROM will place an SPD characteristics block on the SDA signal line, from which the cache controller 120 will extract size and speed information; typically from bytes 0 and 10 of the SPD data, although other SPD data formats can be used.

In step 440, the cache controller 120 determines if the access time of the cache memory module 220 is acceptable. If the access time obtained from the SPD block is higher than a predetermined value that the cache controller 120 can handle, then the memory module validation fails in step 445 and the cache controller 120 marks that cache memory module 220 as ignored in step 450.

Cache controllers 120 typically support only one access time for cache memory modules 220, however, the cache controller 120 can alternatively be configured to access the memory modules 220 using different access times.

If the access time reported by the cache memory module 220 is acceptable, then the cache controller 120 determines whether the size reported by the cache module 220 is acceptable in step 455. Although as shown in FIGS. 4a-4b, the cache controller 120 examines the access time then the size, in another embodiment, the size can be examined before examining the access time.

The size comparison of step 455 is based upon the amount of tag memory 140 available. Step 457 determines if the size is larger than the available tag memory can support. If not, then in step 485, the cache memory controller 120 indicates failure in validating the cache memory module 220 and marks the cache memory module 220 as ignored in step 490. Otherwise, in step 458, a warning can be indicated that some of the new cache memory module 220 will not be used. In step 459, the cache controller is configured to use only the maximum size cache memory supported by the tag memory 140.

In another disclosed embodiment, instead of failing a cache memory module 220 that is too big, the cache controller 120 can mark only a portion of the cache memory module 220 as in use, ignoring the excess memory capacity of the cache module 220.

Once validation indicates the cache memory module 220 is acceptable in step 460, the tag memory 140 is flushed in step 465.

It is contemplated that step 465 can be omitted if the tag memory 140 is external tag memory and additional tag memory can be added along with the cache memory insertion.

Once the tag memory 140 is flushed, then in step 470 the tag 140 must be reconfigured to indicate additional cache lines are associated with each tag in tag memory. For example, if the cache memory is initially operated as a direct-mapped tag memory, after insertion the tag may be operated as a 2-way set associative memory, with each tag having 2 cache lines instead of 1. Other types of tag memory reconfiguration can also be done.

Then in step 475, the newly inserted cache memory module 220 is initialized. The cache controller 120 writes a predetermined value, typically zero, to each memory location of the newly inserted cache memory module 220. Finally, in step 480, the cache controller 120 indicates the additional cache memory module 220 is usable. In one embodiment, a status bit is set in a register of the cache controller 120 to indicate usability of the added cache memory module 220.

Turning to FIGS. 4c and 4d, flow charts illustrate corresponding steps for validating a cache memory module 220 without an auto-detect capability. Unlike the auto-detect technique of FIGS. 4a-4b, the technique of FIG. 4c may not determine the actual access time of the cache module 220, but merely determines whether the cache memory module 220 can support an acceptable access time.

In step 429, the cache controller 120 sets a default access time. Using that default access time, in step 434 the cache controller 120 writes a predetermined value, typically non-zero at a predetermined memory location. Then in step 439, the memory location is read. In step 444, the value read is compared to the value written. If the comparison fails, then in step 464 the cache controller 120 determines whether the access time used was the default value. If so, then failure is indicated in step 469 and the cache memory module 220 is ignored in step 474. Otherwise, an access time is set in step 459. If the step 444 indicates the value read in step 439 is the same as written in step 434, the access time is decremented in step 449. If the new access time is a valid access time supported by the cache controller 120 as indicated in step 454, then steps 434-449 are repeated as shown. Otherwise, the access time is set in step 459 at the previous access time value. The decrement in step 449 can be any value convenient for the system designer. Then the cache controller 120 proceeds to step 427 of FIG. 4d to determine the size of the cache memory module 220.

As shown in FIG. 4c, the default access time is set at a slowest acceptable access time for the controller 120, then decremented to locate a fastest acceptable access time supported by both the cache memory module 220 and the cache controller 120. In one disclosed embodiment, the cache controller adjusts its clock skew to synchronize to the access time, thus supporting more than one possible access time. One skilled in the art will recognize that other techniques could be used to vary the access time for determining the access time of the cache memory module. If the cache controller 120 supports only a single access time, then the repetition of steps 439-454 can be omitted.

Turning now to FIG. 4d, similar steps determine whether the cache memory module 220 has an acceptable size. In steps 427 and 432, a predetermined data value, typically non-zero, is first written, then read back from a first memory location in the new cache memory module 220. The first memory location can be any address value determined by the system designer. Typically, the address value corresponds to a minimum acceptable size value. In step 437, if the data value read in step 432 matches the data value written in step 427, then the memory address of the memory location is incremented in step 442. The write, then read sequence is repeatedly performed until the data value read in step 432 does not match the data value written in step 427, indicating the highest memory address of the cache memory module 220 has been exceeded. In step 447, if the failure occurred at the first memory location, then the cache memory module is indicated as not acceptable in step 457. Then in step 462, the cache controller 120 ignores the unacceptable cache memory module 220. Otherwise, in step 452 the size of the cache memory module 220 is calculated, comparing the initial memory address and the final memory address of the repeated steps 427-437. The cache controller 120 then continues with step 455 of FIG. 4b as explained above.

Further, although shown in FIGS. 4c-4d as computed separately, one skilled in the art will recognize the size and access time determination can be performed in either order or simultaneously, as convenient for the system designer.

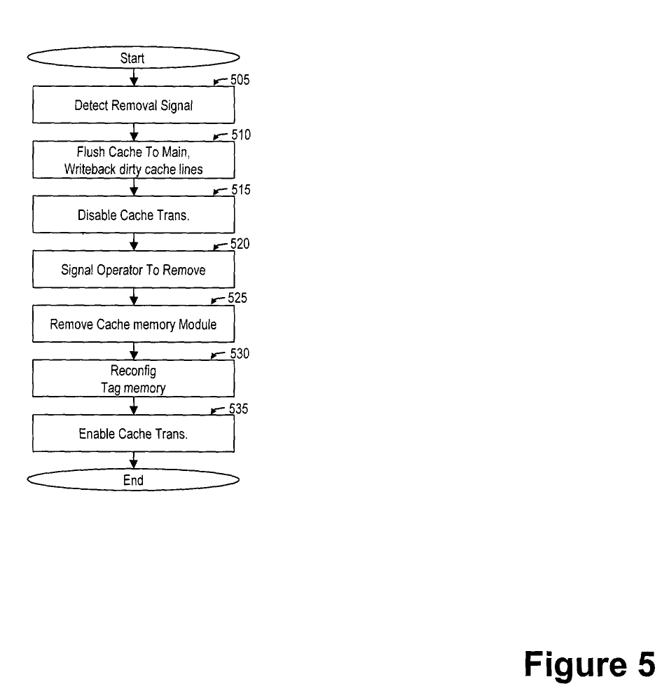

Turning now to FIG. 5, a flow chart illustrates a technique for hot-plug removal of a cache memory module 220. First, an operator signals an intent to remove a cache memory module 220 in step 505, using a similar technique as for inserting a cache module 220 in step 405 of FIG. 4a. Upon detection of this signal, the cache memory module 220 is flushed to the main memory 160 in step 510, writing back any dirty cache lines, using conventional cache flushing procedures of the cache controller 120. Then the cache controller 120 disables further cache transactions for the duration of the removal operation in step 515. In one embodiment, this step is performed by asserting a hold-off signal on the host bus 170, which stalls the processor 110. One example of a hold-off signal is the AHOLD signal of the PENTIUM processor from Intel Corporation. Other disable techniques can be used. Once cache transactions are disabled, the operator is signaled to proceed with the removal, using similar techniques as recited above for insertion in step 410 of FIG. 4a. The operator removes the cache memory module 220 in step 525. The cache controller 120 reconfigures the tag memory 140 in step 530, using a reverse technique from that of step 470 of FIG. 4b as recited above, to indicate that the portion of the tag memory 140 corresponding to the removed cache memory module 220 is no longer is use, which may reduce the number of cache lines associated with a given tag. Finally, the cache controller 120 enables further cache transactions in step 535. If the hold-off signal was asserted in step 515, then step 535 deasserts the hold-off signal, ending the processor 110 stall.

One skilled in the art will recognize that the flowcharts of FIGS. 4a-4c and 5 are exemplary and illustrative, and alternate steps and implementations are possible. Further, the illustrated steps can be implemented in multiple ways, including software, firmware, or hardware.

Replacing an existing cache memory module 220 is performed by first removing the cache memory module 220 as in FIG. 5, then inserting the replacement cache memory module 220 as in FIGS. 4a-4c.

The foregoing disclosure and description of the preferred embodiment are illustrative and explanatory thereof, and various changes in the components, circuit elements, circuit configurations, and signal connections, as well as in the details of the illustrated circuitry and construction and method of operation may be made without departing from the spirit and scope of the invention.

We claim:

1. A method of hot plug insertion of cache memory, comprising the steps of:
signaling a cache memory controller to start an insertion operation;
hot-plug inserting a cache memory module into an open cache memory slot;
validating the cache memory module characteristics; and
if the step of validating the cache memory module characteristics successfully validates the cache memory module characteristics, indicating successful insertion of the cache memory module.

2. The method of claim 1, further comprising the steps of:
flushing a cache tag memory; and
reconfiguring the cache tag memory.

3. The method of claim 2, the step of reconfiguring the cache tag memory comprising the step of:
marking an unused portion of the tag memory as being in use, the unused portion corresponding to a size of the cache memory module.

4. The method of claim 1, the step of validating the cache memory module characteristics comprising the steps of:
waiting a predetermined time after completion of the step of inserting the cache memory module;
determining a size of the cache memory module;
determining an access time acceptability of the cache memory module; and
if the cache memory module access time is not acceptable, indicating failure, otherwise indicating successful validation.

5. The method of claim 4, wherein the cache memory module can report module characteristics,
the step of determining a size of the cache memory module comprising the steps of:
issuing a request to the cache memory module for the size of the cache memory module; and
receiving the size of the cache memory module responsive to the step of issuing a request.

6. The method of claim 5, wherein the cache memory module supports auto-detection,
the step of issuing a request comprising the step of:
issuing an auto-detection read request;
the step of receiving comprising the steps of:
receiving an auto-detection characteristics block responsive to the auto-detection read request; and
extracting the size from the auto-detection characteristics block.

7. The method of claim 4, wherein the cache memory can report module characteristics,
the step of determining the access time of the cache memory module comprising the steps of:
issuing a request to the cache memory module for the access time of the cache memory module;
receiving the access time from the cache memory module responsive to the step of issuing;
if the access time is at least as great as a predetermined access time value, indicating the access time is acceptable; and
otherwise, indicating the access time is unacceptable.

8. The method of claim 7, wherein the cache memory module supports auto-detection,
the step of issuing a request comprising the step of:
issuing an auto-detection read request;
the step of receiving comprising the steps of:
receiving an auto-detection characteristics block responsive to the auto-detection read request; and
extracting the access time from the auto-detection characteristics block.

9. The method of claim 4, the step of determining a size comprising the steps of:
(a) writing a predetermined value to an address location of the cache memory module;
(b) reading the address location, receiving a read value;
(c) comparing the read value to the predetermined value;
(d) if the read value equals the predetermined value, incrementing the address location and repeating steps (a)-(d); and
(e) otherwise, computing the cache memory module size from the current value of the address location.

10. The method of claim 4, the step of determining an access time comprising the steps of:
writing a predetermined value to a location of the cache memory module;
reading the location, receiving a read value;
comparing the read value to the predetermined value; and
if the read value equals the predetermined value, indicating the access time is acceptable;
otherwise, indicating the access time is unacceptable.

11. The method of claim 1, further comprising the step of:
setting a status bit to indicate successful insertion of the cache memory.

12. The method of claim 1, further comprising the step of:
initializing the cache memory module by writing a predetermined value to every memory location of the cache memory module.

13. A method of hot-plug removal of cache memory, comprising the steps of:
signaling a cache memory controller to start a removal operation;
flushing the cache memory to a main memory;
disabling further cache transactions;
hot-plug removing the cache memory module;
reconfiguring a tag memory for the cache controller; and
enabling further cache transactions.

14. The method of claim 13, the step of reconfiguring a tag memory comprising the steps of:
marking a portion of the tag memory corresponding to the cache memory module as unused.

15. The method of claim 13,
the step of disabling further cache transactions comprising the step of:
asserting a hold-off signal to a processor coupled to the cache memory controller; and
the step of enabling further cache transactions comprising the step of:
deasserting the hold-off signal.

16. A method for hot-plug replacing cache memory, comprising the steps of:
hot-plug removing a cache memory module;
hot-plug inserting a replacement cache memory module; and
reconfiguring a tag memory for a cache memory controller to correspond to the replacement cache memory module.

17. A cache memory subsystem adapted for hot-plug insertion and removal of cache memory comprising:
a plurality of slots for insertion of cache memory modules;
a tag memory; and
a cache controller, coupled to the tag memory and the plurality of slots, comprising:
circuitry to detect insertion of a cache memory module in one of the plurality of slots;
circuitry to validate a cache memory module detected by the circuitry for detecting; and
circuitry to indicate successful insertion of the cache memory module.

18. The cache memory subsystem of claim 17, the cache controller further comprising:
circuitry to flush the tag memory responsive to insertion of a cache memory module into one of the plurality of slots; and
circuitry to allocate an unused portion of the tag memory to the cache memory module.

19. The cache memory subsystem of claim 17, the circuitry for validating the cache memory module comprising:
a timer adapted to start a predetermined delay period upon insertion of the cache memory module;
circuitry to determine characteristics of the cache memory module upon expiration of the predetermined delay period; and
circuitry to indicate successful validation if the characteristics of the cache memory module are acceptable, otherwise to indicate failure.

20. The cache memory subsystem of claim 19, the circuitry to determine characteristics of the cache memory module comprising:
circuitry to determine a memory capacity of the cache memory module.

21. The cache memory subsystem of claim 20, wherein the cache memory module supports auto-detection,
the circuitry to determine a memory capacity comprising:
circuitry to send an auto-detection read signal to the cache memory module;
circuitry to read an auto-detection block from the cache memory module; and
circuitry to extract a memory capacity from the auto-detection block.

22. The cache memory subsystem of claim 20, wherein the cache memory module does not support auto-detection,
the circuitry to determine a memory capacity comprising:
circuitry to repeatedly write a predetermined value then read the cache memory until reading fails to return the predetermined value.

23. The cache memory subsystem of claim 19, the circuitry to determine characteristics of the cache memory module comprising:
circuitry to determine a memory access time of the cache memory module.

24. The cache memory subsystem of claim 23, wherein the cache memory module supports auto-detection,
the circuitry to determine a memory access time comprising:
circuitry to send an auto-detection read signal to the cache memory module;
circuitry to read an auto-detection block from the cache memory module; and
circuitry to extract a memory access time from the auto-detection block.

25. The cache memory subsystem of claim 23, wherein the cache memory module does not support auto-detection,
the circuitry to determine a memory access time comprising:
circuitry to write then read the cache memory with a predetermined value;
circuitry to indicate a memory access time of a predetermined access time if the circuitry to write then read successfully reads data written to the cache memory module; otherwise, to indicate an access time greater than the predetermined access time for the cache memory module.

26. The cache memory subsystem of claim 19, the circuitry to indicate successful validation comprising:
circuitry to indicate successful validation if the memory access time is not greater than a predetermined access time, otherwise to indicate failure.

27. The cache memory subsystem of claim 17, the cache controller further comprising:
circuitry to flush cache memory to a main memory upon beginning a cache memory module removal operation;
circuitry to indicate removal of a cache memory module can be performed; and
circuitry to mark a portion of the tag memory corresponding to the cache memory module as unused.

28. The cache memory subsystem of claim 27, the cache controller further comprising:
circuitry to prevent further cache memory transactions upon beginning a cache memory removal operation; and
circuitry to allow further cache memory transactions upon completion of a cache memory module removal operation.

29. The cache memory subsystem of claim 28, the circuitry to prevent further cache memory transactions comprising:
circuitry to assert a hold-off signal to a processor coupled to the cache memory controller.

30. The cache memory subsystem of claim 28, the circuitry to allow further cache memory transactions comprising:
circuitry to deassert a hold-off signal to a processor coupled to the cache memory controller.
